(19) United States
(12) Patent Application Publication
(10) Pub. No.: US 2020/0123665 A1
(43) Pub. Date: Apr. 23, 2020

(54) BONDING SUBSTRATE AND METHOD FOR PROTECTING SURFACES INTENDED FOR WIRE BONDING

(71) Applicant: Doduco Solutions GmbH, Pforzheim (DE)

(72) Inventors: Joachim Ganz, Kapfenhardt (DE); Uwe Dreissigacker, Engelsbrand (DE); Isabell Buresch, Illertissen (DE); Boris Mizaikoff, Ulm (DE); Dervis Türkmen, Leipheim (DE)

(21) Appl. No.: 16/722,179

(22) Filed: Dec. 20, 2019

Related U.S. Application Data
(63) Continuation of application No. PCT/EP2018/064775, filed on Jun. 5, 2018.

(30) Foreign Application Priority Data
Jun. 22, 2017 (DE) 10 2017 113 871.4

(51) Int. Cl. C23F 11/14; C23C 22/52; C23C 22/68; H01L 23/498; H01L 23/495

(52) U.S. Cl. CPC C23F 11/141; C23C 22/52; C23F 11/149; H01L 23/49586; H01L 23/49811; H01L 23/49894; C23C 22/68

(57) ABSTRACT

A bonding substrate is described having a contacting pad made of copper or a copper-based alloy for bonding wire, the contacting pad being covered with a corrosion inhibitor layer containing a nitrogen-containing aliphates as an active substance and a nitrogen-containing heterocyclic aromatics as a further active substance. The corrosion inhibitor layer, without any water content, contains 5% by weight or more of urea derivative or 3% by weight or more of triphenylguanidine or 2% by weight or more of tetrazole derivative or 5% by weight or more of 1-H-benzotriazole or 5% by weight or more of benzimidazole. In addition, an electronic module having such a bonding substrate and a method of protecting from corrosion surfaces made of copper or a copper-base alloy provided for wire bonding are disclosed.

### RELATED APPLICATIONS

This application is a continuation of PCT/EP2018/064775, filed Jun. 5, 2018, which claims priority to DE 10 2017 113 871.4, filed Jun. 22, 2017, the entire disclosures of both of which are hereby incorporated herein by reference.

### BACKGROUND

This disclosure relates to bonding substrates having surfaces made of copper or copper-based alloy and to a method for protecting surfaces made of copper or copper-based alloy intended for wire bonding. A bonding substrate of this type is generally known from WO 2014/027566 A1.

A bonding substrate has a contact pad made of copper or a copper-based alloy, which is provided for bonding a wire made of copper or a copper-based alloy. Wire is welded to the copper or copper-based alloy of the contact pad during bonding. Various methods are common for this purpose, for example, thermocompression bonding, thermosonic ball wedge bonding and ultrasonic wedge-wedge bonding.

Surfaces made of copper or copper-based alloys are susceptible to corrosion. Oxide layers on copper surfaces can make difficult or even prevent the bonding of wires to the surfaces. Copper surfaces can be coated with aluminum, aluminum-silicon alloys, silver or other corrosion-resistant metals in order to protect bonding substrates or their contact pads intended for bonding. However, known plating methods cause considerable expense.

WO 2016/124 382 A1 discloses protecting aluminum-copper composite semi-finished products from corrosion by a lacquer containing acrylate polymer. However, such an acrylate polymer must be removed before bonding and therefore causes considerable expense.

### SUMMARY

This disclosure shows how surfaces of copper or copper-based alloys intended for wire bonding can be protected from corrosion with less effort, without a separate operation being required to remove a protective layer before bonding.

According to this disclosure, this is achieved by an organic corrosion inhibitor layer which is applied to the copper surface or the surface of a copper-based alloy and which contains a nitrogen-containing aliphatic hydrocarbon as an active substance. Aliphatic hydrocarbons are also referred to as aliphates for short. Heteroatom-containing aliphates, in particular nitrogen-containing and/or sulfur-containing aliphates, can adhere well to copper surfaces through van der Waals forces and have an oxidation-inhibiting effect, in particular when nitrogen-containing aliphates are used, which have a reductive effect. In this way, contact pads of bonding substrates can effectively and inexpensively protect against corrosion.

The corrosion inhibitor layer is applied in a method according to this disclosure as a liquid layer, namely, as an aqueous solution. The liquid layer can then form a solid corrosion inhibitor layer, for example, by drying, or remain liquid, that is, form a liquid corrosion inhibitor layer. After or during the drying of the applied solution, constituents contained therein can crosslink, that is, form a polymer layer.

The heteroatom-containing aliphates in a corrosion inhibitor layer according to this disclosure can be, for example, urea derivatives or guanidine derivatives, for example, triphenylguanidine. The corrosion inhibitor layer, without any water content, preferably contains at least 20% by weight of nitrogen-containing aliphates, more preferably at least 40% by weight. In the following, data in % by weight refer to the corrosion inhibitor layer without any water content, that is, its dry mass.

This disclosure provides that the corrosion inhibitor layer contains, as a further active substance, a nitrogen-containing heterocyclic aromatic, for example, a tetrazole and/or triazole derivative. Alternatively or additionally, for example, aniline derivatives and isocyanatobenzene can be used as nitrogen-containing heterocyclic aromatics. Heterocyclic aromatics, because of their aromatic ring that contains both heteroatoms, for example, nitrogen or sulfur, and carbon atoms, have a free electron pair which allows a particularly good adhesion to a metallic surface.

A further advantageous refinement of this disclosure provides that the or one of the nitrogen-containing active substance(s) of the corrosion inhibitor layer additionally contain(s) sulfur. For example, isothiocyanatobenzene can be used as such an active sub stance.

Effective constituents of the corrosion inhibitor layer can be, for example, urea derivatives and/or aniline derivatives, preferably in combination with tetrazole derivatives. Alternatively or additionally, the corrosion inhibitor layer can contain triphenylguanidine and/or phenylurea and/or isothiocyanatobenzene and/or tetrazole derivative as effective constituents. The corrosion inhibitor layer can be applied as an aqueous solution in which the effective constituents can, for example, have a content of from 2 to 10% by weight. Particularly suitable tetrazole derivatives are, in particular, 1-phenyl-1H-tetrazole-5-thiol and/or sodium 1-phenyl-1H-tetrazole-5-thiolate, preferably in a solution having a pH value of from 9 to 12.

Without the water content, the corrosion inhibitor layer consists preferably at least 10% by weight, more preferably at least 30% by weight, of one or more urea derivatives and one or more aniline derivatives and one or more tetrazole derivatives and/or triphenylguanidine and/or phenylurea and/or Isothiocyanatobenzene and/or tetrazole derivative. The corrosion inhibitor layer, without the water content, particularly preferably consists predominantly of one or more urea derivatives and one or more aniline derivatives and/or triphenylguanidine and/or phenylurea and/or isothiocyanatobenzene and one or more tetrazole derivatives.

The following parts by weight each refer to the corrosion inhibitor layer without the water content. When applied, the corrosion inhibitor layer can have a significant water content, for example, from 50% to 95% by weight.

For example, the corrosion inhibitor layer can contain 5% by weight or more, preferably 20% by weight or more, more preferably 30% by weight or more, of urea derivative.

Alternatively or additionally, the corrosion inhibitor layer can contain 5% by weight or more, preferably 20% by weight or more, more preferably 30% by weight or more, of aniline derivative.

Alternatively or additionally, the corrosion inhibitor layer can contain 3% by weight or more, preferably 20% by weight or more, more preferably 30% by weight or more, of triphenyl guanidine.

Alternatively or additionally, the corrosion inhibitor layer can contain 5% by weight or more, preferably 20% by weight or more, more preferably 30% by weight or more, of phenylurea.

Alternatively or additionally, the corrosion inhibitor layer can contain 10% by weight or more, preferably 20% by weight or more, more preferably 30% by weight or more, of isothiocyanatobenzene.

Alternatively or additionally, the corrosion inhibitor layer can contain 5% by weight or 10 more, preferably 10% by weight or more of tetrazole derivative. Preferably, the corrosion inhibitor layer contains no more than 30% by weight of tetrazole derivative.

The corrosion inhibitor layer can be inexpensively applied as a liquid and form a thin layer so that it does not have to be removed prior to bonding. Preferably, the corrosion inhibitor layer has a thickness of not more than 400 nm. Even a corrosion inhibitor layer having a maximum thickness of 100 nm or less is sufficient for effective corrosion protection, for example, a corrosion inhibitor layer having a thickness of not more than 50 nm. In general, a thickness of 10 nm is sufficient, only rarely are thicknesses of 30 nm or more required for effective corrosion protection.

Alternatively or additionally, the corrosion inhibitor layer can contain 1-H-benzotriazole and/or benzimidazole and/or phosphates as an effective constituent. In addition, the corrosion inhibitor layer can contain organic and/or inorganic acid, for example, phosphate and/or sulfuric acid. The corrosion inhibitor layer, without any water content, can contain, for example, 1% by weight of phosphate or more, about 5% by weight of phosphate or more. In this way, it is possible to realize an acidic corrosion inhibitor layer which preferably has a pH value of 4.0 or less, in particular 3.5 or less, for example, 3.0 or less. However, the corrosion inhibitor layer can also be weakly acidic, neutral or weakly basic, for example, by containing, as effective constituents, benzimidazoles and/or ethylene glycol isopropyl ether and/or aniline and/or isothiocyanatobenzene and/or 1-H-benzotriazole and/or bisphenol A ethoxylate. In this case, for example, a pH value of 4 to 8 can be advantageous.

An advantageous refinement of this disclosure provides that the corrosion inhibitor layer contains at least 10% by weight of 1-H-benzotriazole and/or benzimidazole, preferably at least 20% by weight of 1-H-benzotriazole and/or benzimidazole, wherein these specifications refers to the corrosion inhibitor layer without water content. When the corrosion inhibitor layer contains water, the content of 1-H-benzotriazole and/or benzimidazole can thus be lower based on the total weight.

The bonding substrate can be formed as a body which is properly inserted into a frame around which a frame is produced by injection molding, for example, the bonding substrate can be a stamped part or an inlay. A part of the surface of this body forms a contacting pad, that is, it is intended for bonding wire. Such bonding substrates often have patterned leadframes which then sit in compartments of a frame adapted to this purpose so that the contacting pad is exposed. However, a corrosion inhibitor layer according to this disclosure can be used to protect a copper or copper-based alloy surface which is provided for bonding wire and thus forms a contacting pad, of an arbitrarily shaped bonding substrate.

### BRIEF DESCRIPTION OF THE DRAWINGS

The above-mentioned aspects of exemplary embodiments will become more apparent and will be better understood by reference to the following description of the embodiments taken in conjunction with the accompanying drawings, wherein:

FIG. 1 shows a section of an electronic module having a frame with compartments in which bonding substrates are arranged with contacting pads.

### DESCRIPTION

The embodiments described below are not intended to be exhaustive or to limit the invention to the precise forms disclosed in the following description. Rather, the embodiments are chosen and described so that others skilled in the art may appreciate and understand the principles and practices of this disclosure.

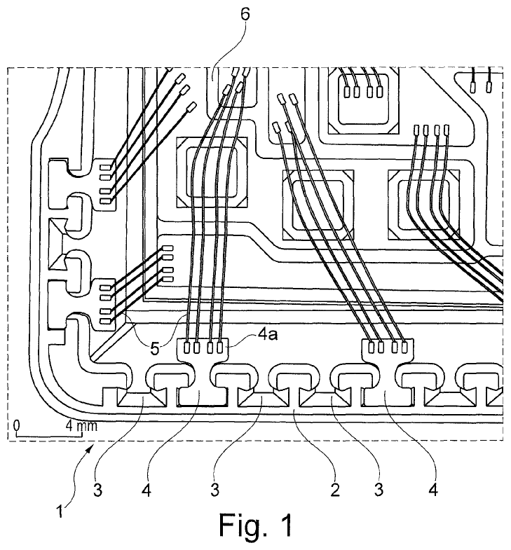

FIG. 1 shows a section of an electronic module 1 which has a frame 2 having compartments 3. Bonding substrates 4 are arranged in some of the compartments 3, which bonding substrates can have an H-shaped cross-section. The bonding substrates 4 have contacting pads 4a, the bonding wires 5 of which are fastened, which lead to a printed circuit board 6.

The contacting pads 4a of the bonding substrate 4 are made of copper or a copper-based alloy, for example CuNi₃SiMg, and are therefore susceptible to corrosion. The bonding substrates 4 or at least their contacting pads 4a are therefore covered with an organic corrosion inhibitor layer after their production.

The corrosion inhibitor layer is applied as an aqueous solution, for example, by dipping or spraying. After the application, the corrosion inhibitor layer can lose water and become a solid layer or remain a liquid layer.

For example, an acidic, aqueous solution of 1-H-benzotriazole and/or benzimidazole can be the corrosion inhibitor layer. The pH value of such a solution is preferably below 4.0, for example below 3.5, or even below 3.0. The solution preferably contains one or more inorganic acids, for example, phosphoric acid and/or sulfuric acid. In addition, such a corrosion inhibitor layer preferably contains phosphates, for example, 1% by weight or more. For example, 10 ml of 1-H-benzotriazole and/or 10 ml of benzimidazole are mixed with 1 liter of water and then applied to produce such a corrosion inhibitor layer. For example, 10 ml of inorganic acids such as phosphoric acid or sulfuric acid can be added to this mixture, wherein phosphates in addition to the acid can be dissolved, for example, 1 to 10 mg of ammonium molybdophosphate.

Such a corrosion inhibitor layer shows no negative effects on the bondability of a 300 μm Cu wire to a CuNi₃SiMg bonding substrate surface and on a leadframe surface punched therefrom.

For example, a corrosion inhibitor consisting of 1-phenyl-1H-tetrazole-5-thiol and/or sodium 1-phenyl-1H-tetrazole-5-thiolate in combination with urea derivatives and/or aniline derivatives and/or triphenylguanidine can also be used for the corrosion inhibitor layer, wherein such a corrosion inhibitor layer preferably additionally contains phenylurea and isothiocyanatobenzene. For this purpose, for example, 20 ml of such a corrosion inhibitor are mixed with 1 liter of water and then this aqueous solution is applied to a bonding substrate 4. The solution can dry on the bonding substrate and form a solid layer by crosslinking.

For example, a corrosion inhibitor can be used produced by mixing 10 mg of 1-phenyl-1-H-tetrazole-5-thiol, 10 mg of sodium 1-phenyl-1H-tetrazole-5-thiolate, 10 mg of one or more urea derivatives, 10 mg of one or more aniline derivatives, 10 mg of triphenylguanidine, 10 mg of phenylurea and 10 mg of isothiocyanatobenzene, wherein 1 liter of water is added to this mixture.

A further possibility consists in using benzimidazoles and ethylene glycol isopropyl ether as a corrosion inhibitor. Alternatively, aniline and/or isothiocyanatobenzene and/or 1-H-benzotriazole can each be used in combination with bisphenol A ethoxylate, wherein an acid can be added, for example, an organic acid such as acetic acid. 100 ml to 200 ml of this corrosion inhibitor can be mixed with 1 liter of water and then applied as an aqueous solution to a bonding substrate.

While exemplary embodiments have been disclosed hereinabove, the present invention is not limited to the disclosed embodiments. Instead, this application is intended to cover any variations, uses, or adaptations of this disclosure using its general principles. Further, this application is intended to cover such departures from the present disclosure as come within known or customary practice in the art to which this invention pertains and which fall within the limits of the appended claims.

### LIST OF REFERENCE NUMBERS

1 electronic module
2 frames
3 compartment
4 bonding substrate
4a contacting pad
5 wire
6 printed circuit board

What is claimed is:

1. A bonding substrate, comprising:
a contacting pad made of copper or a copper-based alloy configured for bonding wire;
a corrosion inhibitor layer covering the contacting pad, the corrosion inhibitor layer containing nitrogen-containing aliphates as an active substance and nitrogen-containing heterocyclic aromatics as a further active substance;
wherein the corrosion inhibitor layer, without any water content, contains 5% by weight or more of urea derivative or 3% by weight or more of triphenylguanidine or 2% by weight or more of tetrazole derivative or 5% by weight or more of 1-H-benzotriazole or 5% by weight or more of benzimidazole.

2. The bonding substrate according to claim 1, wherein the corrosion inhibitor layer contains more aliphates than heterocyclic aromatics.

3. The bonding substrate according to claim 1, wherein the corrosion inhibitor layer, without any water content, contains at least 10% by weight of one or more of the following substances: urea derivates, aniline derivatives, triphenylguanidine, phenylurea, isothiocyanatobenzene and/or tetrazole derivatives.

4. The bonding substrate according to claim 1, wherein the corrosion inhibitor layer, without any water content, contains at least 10% by weight of tetrazole derivative.

5. The bonding substrate according to claim 1, wherein the tetrazole derivative is 1-phenyl-1H-tetrazole-5-thiol and/or sodium 1-phenyl-1H-tetrazole-5-thiolate.

6. The bonding substrate according to claim 1, wherein the corrosion inhibitor layer, without any water content, contains at least 8% by weight of 1-H-benzotriazole and/or benzimidazole.

7. The bonding substrate according to claim 1, wherein the pH of the corrosion inhibitor layer is less than 4.0.

8. The bonding substrate according to claim 7, wherein the corrosion inhibitor layer, without any water content, contains at least 1% by weight of phosphates.

9. The bonding substrate according to claim 1, wherein the corrosion inhibitor layer has a pH of 9 to 12.

10. The bonding substrate according to claim 1, wherein the corrosion inhibitor layer, without any water content, contains at least 10% by weight of one or more of the following substances: benzimidazoles, ethylene glycol isopropyl ether, aniline, isothiocyanatobenzene, 1-H-benzotriazole, bisphenol A ethoxylate.

11. The bonding substrate according to claim 1, wherein the corrosion inhibitor layer has a thickness of not more than 400 nm.

12. An electronics module, comprising a frame having compartments and bonding substrates according to claim 1 arranged in the compartments.

13. A method for protecting from corrosion surfaces made of copper or a copper-based alloy provided for wire bonding, the method comprising:
covering the corrosion surfaces with an organic corrosion inhibitor layer containing a nitrogen-containing aliphate as an active substance and a nitrogen-containing heterocyclic aromatic as a further active substance, wherein the corrosion inhibitor layer, without any water content, contains 5% by weight or more of urea derivative or 3% by weight or more of triphenylguanidine or 2% by weight or more of tetrazole derivative or 5% by weight or more of 1-H-benzotriazole or 5% by weight or more of benzimidazole.

14. The method according to claim 13, wherein the corrosion inhibitor layer is applied as an aqueous solution.
